(19) United States
(12) Patent Application Publication
(10) Pub. No.: US 2022/0075980 A1
(43) Pub. Date: Mar. 10, 2022

(54) DISPLAY DEVICE

(71) Applicant: SAMSUNG DISPLAY CO., LTD., YONGIN-SI (KR)

(72) Inventors: JONG HYUN LEE, Suwon-si (KR); Eun Jin SUNG, Yongin-si (KR); Kyung Tea PARK, Seoul (KR); Kang Bin JO, Suwon-si (KR); Go Eun CHA, Suwon-si (KR)

(21) Appl. No.: 17/406,299

(22) Filed: Aug. 19, 2021

(30) Foreign Application Priority Data
Sep. 4, 2020 (KR) 10-2020-0112788

(51) Int. Cl. G06K 9/00; H01L 51/52; H01L 27/32

(52) U.S. Cl. CPC G06K 9/0004; H01L 27/3276; H01L 27/3234; H01L 51/5284

(57) ABSTRACT

A display device includes a light emitting electrode on a thin film transistor layer. The thin film transistor layer includes a lower metal layer on a substrate and a semiconductor layer above and overlapping the lower metal layer. The lower metal layer includes a plurality of curved portions. Edges of respective ones of the curved portions are on concentric circles having substantially a same center point and an edge of the semiconductor layer is on the lower metal layer.

### CROSS-REFERENCE TO RELATED APPLICATION

This application claims priority from Korean Patent Application No. 10-2020-0112788 filed on Sep. 4, 2020 in the Korean Intellectual Property Office, and all the benefits accruing therefrom under 35 U.S.C. 119, the contents of which in its entirety are herein incorporated by reference.

### BACKGROUND

### 1. Technical Field

One or more embodiments described herein relate to a display device.

### 2. Description of the Related Art

Various attempts have been made to protect personal information stored in an electronic device that has a display device. One attempt involves performing user authentication based on fingerprint detection. This may be accomplished using a fingerprint recognition sensor disposed in either a display area or non-display area (e.g., bezel). When a fingerprint recognition sensor is in the display area, a light blocking layer (that blocks ambient light incident on the sensor pixels of the fingerprint recognition sensor) may also be in the display area.

### SUMMARY

In accordance with one or more embodiments, a display device is provided which increases the amount of light focused on a fingerprint recognition sensor in a display area.

In accordance with these or other embodiments, a display device is provided which reduces or prevents the likelihood of a crack forming, for example, during a process of applying a laser beam to a semiconductor layer to achieve silicon crystallization.

In accordance with these or other embodiments, a display device is provided which prevents a voltage drop from occurring in a source voltage line, by electrically connecting a lower metal layer to the source voltage line.

In accordance with one or more embodiments, a display device includes a substrate, a thin film transistor layer on the substrate, and a light emitting electrode on the thin film transistor layer. The thin film transistor layer includes a lower metal layer on the substrate and a semiconductor layer above and overlapping the lower metal layer. The lower metal layer includes a plurality of curved portions. Edges of respective ones of the curved portions are on concentric circles having substantially a same center point, and an edge of the semiconductor layer is on the lower metal layer.

In accordance with one or more embodiments, a display device includes a substrate, a lower metal layer on the substrate and including a plurality of curved portions, a semiconductor layer above the lower metal layer in an overlapping manner, a first gate wiring layer on the semiconductor layer and including a (k−1)th scan line and a kth scan line disposed in parallel with each other, and a kth light emitting line disposed in parallel with the (k−1)th scan line and the kth scan line. In addition, the display device includes a second gate wiring layer on the first gate wiring layer and including an initialization voltage line configured to receive an initialization voltage and a connection electrode electrically connected to the lower metal layer, a data wiring layer on the second gate wiring layer and including a jth data line crossing the (k−1)th scan line and the kth scan line, and a first driving voltage line configured to receive a first driving voltage and which is electrically connected to the connection electrode, and a light emitting electrode on the data wiring layer, Edges of respective ones of the curved portions are on concentric circles have substantially a same center point, and an edge of the semiconductor layer is on the lower metal layer.

Aspects of the present disclosure are not restricted to the ones set forth herein. The above and other aspects will become more apparent to one of ordinary skill in the art to which the present disclosure pertains, by referencing the detailed description of the present disclosure. Also, it should be noted that the effects of the present disclosure are not limited to those examples described above. Other effects of the present disclosure may be achieved and will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 illustrates an embodiment of a display device;

FIG. 2 illustrates a plan view embodiment of the display device;

FIG. 3 illustrates an embodiment of a cross-sectional view of the display device;

FIG. 4 illustrates an embodiment of sub-pixels of a display panel and sensor pixels of a fingerprint recognition sensor;

FIGS. 5 and 6 illustrate examples of light collection through a Fresnel pattern;

FIG. 7 illustrates an embodiment of a sub-pixel;

FIG. 8 illustrates an embodiment of sub-pixels in a fingerprint recognition area;

FIG. 9 illustrates an embodiment including a lower metal layer;

FIG. 10 illustrates an example of projecting an upper conductive layer stacking pattern;

FIG. 11 illustrates the layout of FIG. 8 and the layout of the lower metal layer of FIG. 9 according to an embodiment;

FIG. 12 illustrates an embodiment of an optical system obtained by overlapping and projecting an upper conductive layer stacking pattern and the lower metal layer of FIG. 9;

FIG. 13 illustrates a cross-sectional view taken along line XIII-XIII′ of FIG. 8 according to an embodiment;

FIG. 14 illustrates a cross-sectional view taken along line XIV-XIV′ of FIG. 8 according to an embodiment;

FIG. 15 illustrates a cross-sectional view taken along line XV-XV′ of FIG. 8 according to an embodiment;

FIG. 16 illustrates a layout of a lower metal layer according to an embodiment;

FIG. 17 illustrates the layout of FIG. 8 and the layout of the lower metal layer of FIG. 16 according to an embodiment;

FIG. 18 illustrates an embodiment of an optical system obtained as a result of overlapping and projecting an upper conductive layer stacking pattern and the lower metal layer of FIG. 16;

FIG. 19 illustrates a layout of a lower metal layer according to an embodiment;

FIG. 20 illustrates the layout of FIG. 8 and the layout of the lower metal layer of FIG. 19 according to an embodiment; and

FIG. 21 illustrates an embodiment of an optical system obtained by overlapping and projecting the upper conductive layer stacking pattern and the lower metal layer of FIG. 19.

### DETAILED DESCRIPTION OF THE EMBODIMENTS

Embodiments of the present invention will now be described more fully hereinafter with reference to the accompanying drawings. The description of these embodiments should not be limiting. Rather, these embodiments are provided so that this disclosure is thorough and complete and will fully convey the scope of the invention to those skilled in the art.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. The same reference numbers may indicate the same components throughout the specification.

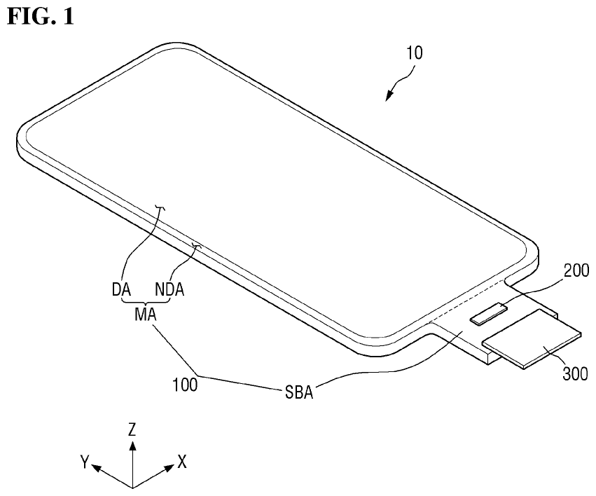

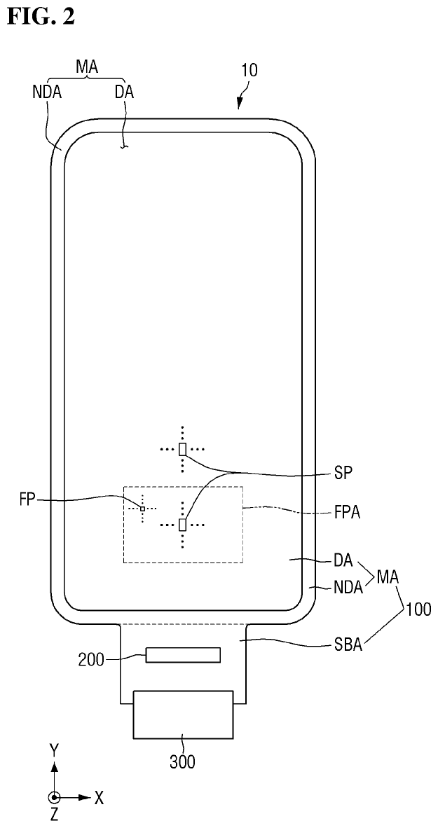

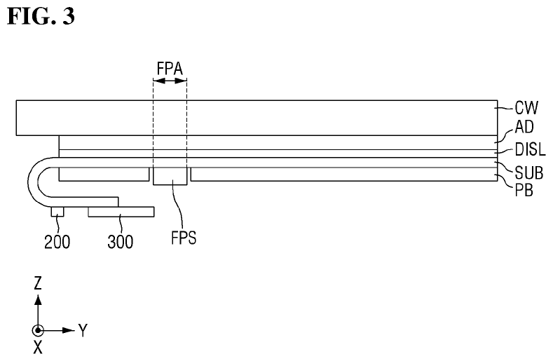

FIG. 1 is a perspective view of a display device 10 according to an embodiment. FIG. 2 is a plan view of the display device 10 according to an embodiment. FIG. 3 is a side cross-sectional view of the display device 10 according to an embodiment. In these drawings, a first direction X may be a direction parallel to a short side of a display device 10 in plan view, for example, a horizontal direction of the display device 10. A second direction Y may be a direction perpendicular to the first direction X, and may be a vertical direction of the display device 10 parallel to the long side of the display device 10 in plan view. A third direction Z may be a direction perpendicular to the first direction X and the second direction Y, and may be a thickness direction of the display device 10.

Referring to FIGS. 1 to 3, the display device 10 displays moving or still images and thus may be used as a display screen for various electronic devices. Examples of these electronic devices include a television, a laptop computer, a monitor, a billboard and an Internet-of-Things (IOT) device. Additional examples include various forms of portable electronic devices, such as, but not limited to, a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device. Examples include an organic light emitting display device using an organic light emitting diode, a quantum dot light emitting display device including a quantum dot light emitting layer, an inorganic light emitting display device including an inorganic semiconductor, and a micro light emitting display device using a micro light emitting diode (LED). For illustrative purposes only, the following description is directed to an example where the display device 10 is an organic light emitting display device.

According to an embodiment, the display device 10 may include a display panel 100, a display driver 200, and a display circuit board 300. The display panel 100 may have a predetermined (e.g., rectangular) shape in a plan view. Corners where adjacent sides of the display panel 100 meet may be right-angled, but may be at a different angle or may have a different shape in another embodiment, e.g., may be rounded. In other embodiments, the planar shape of display panel 100. For example, one or more of the corners may have a polygonal shape, a circular shape, an elliptical shape, or another shape.

The display panel 100 may include a substrate SUB, a display layer DISL disposed on the substrate SUB, and a lower panel cover PB disposed under the substrate SUB. The substrate SUB may be formed of an insulating material (e.g., glass, quartz, polymer resin, etc.), and may be a rigid substrate or flexible substrate, the latter of which can be bent, folded or rolled.

The substrate SUB may include a main region MA and a sub-region SBA, and a display layer DISL may be disposed in the main region MA. The sub-region SBA may protrude from one side of the main region MA in the second direction Y. As shown in FIG. 2, the length of the sub-region SBA in the first direction X may be less than the length of the main region MA in the first direction X. The length of the sub-region SBA in the second direction Y may be less than the length of the main region MA in the second direction Y. The lengths of the sub-region SBA may differ in other embodiments.

In one embodiment, the sub-region SBA may be bent in the third direction Z. The bent sub-region SBA may face the bottom surface of the substrate SUB and may overlap the main region MA in the third direction Z. The display driver 200 and the display circuit board 300 may be disposed in the sub-region SBA.

The main region MA may include a display area DA and a non-display area NDA arranged to surround the display area DA. The display area DA may be an area in which a plurality of sub-pixels SP are arranged to display an image. The non-display area NDA is an area in which no image is displayed, e.g., sub-pixels SP may not be in the non-display area NDA. The display area DA may include the plurality of sub-pixels SP. In one embodiment, the display area DA may also include scan lines, data lines, driving voltage lines and/or other features connected to respective ones of the sub-pixels SP. A scan driver for applying scan signals to the scan lines, fan-out lines for connecting the data lines to the display driver 200, and/or other features may be disposed in the non-display area NDA.

The display area DA may include a fingerprint recognition area FPA that overlaps a fingerprint recognition sensor FPS (examples of which will be described later) and may serve as an area where fingerprints are contacted and recognized. The fingerprint recognition sensor FPS may be at a location where a fingerprint may be easily placed while gripping the display device 10. For example, the fingerprint recognition area FPA may overlap a partial area on the other side in the second direction Y from the central portion of the display area DA. However, the present disclosure is not limited thereto, and the fingerprint recognition sensor FPS may be disposed to overlap the entire display area DA in one embodiment. In this case, the fingerprint recognition area FPA may be substantially the same in size as the display area DA. For simplicity, the following description is directed to the case where the fingerprint recognition area FPA overlaps a partial area on the other side in the second direction Y relative to the central portion of the display area DA, but the present disclosure is not limited thereto.

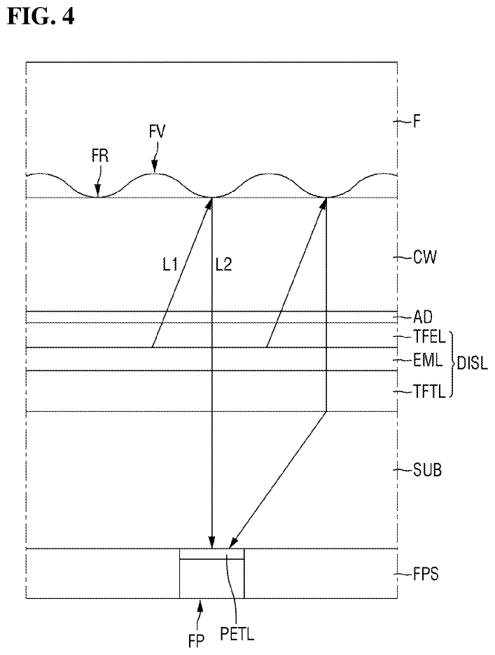

The display layer DISL may be on the substrate SUB and may include pixels and display an image. The display layer DISL may include a thin film transistor layer (e.g., see ‘TFTL’ in FIG. 4), a light emitting element layer (e.g., see ‘EML’ in FIG. 4), and an encapsulation layer (e.g., see ‘TFEL’ in FIG. 4) that seals the light emitting element layer. Example components of the display layer DISL will be described later.

The lower panel cover PB and the fingerprint recognition sensor FPS may be under the substrate SUB. In one embodiment, the lower panel cover PB and the fingerprint recognition sensor FPS may be attached to the bottom surface of the substrate SUB, for example, via an adhesive member or layer. The adhesive member or layer may include, for example, a pressure sensitive adhesive (PSA). The lower panel cover PB may include at least one of a light absorbing member or layer for absorbing external incident light, a buffer member or layer for absorbing external impact, or a heat dissipation member or structure for efficiently dissipating heat from the display panel 100.

The fingerprint recognition sensor FPS may overlap the fingerprint recognition area FPA, but may not overlap the lower panel cover PB in the third direction Z. Examples of a fingerprint recognition method using the fingerprint recognition sensor FPS will be described.

In one embodiment, one or more protective films may be disposed between the substrate SUB and the fingerprint recognition sensor FPS and between the substrate SUB and the lower panel cover PB. The protective film(s) may include, for example, polyimide (PI) or polyethylene terephthalate (PET).

A cover window CW may be on the display layer DISL and may be made of a transparent material, e.g., glass or plastic. In one embodiment, cover window CW may include a polyimide film or an ultra-thin glass (UTG) with a thickness of 0.1 mm or less.

The cover window CW may be attached to the display layer DISL by an adhesive layer AD. For example, the adhesive layer AD may be between the cover window CW and the display layer DISL. In one embodiment, the adhesive layer AD may be a transparent adhesive member, e.g., an optically clear adhesive (OCA) film or another type of adhesive.

The display driver 200 may output signals and voltages for driving the display panel 100. For example, the display driver 200 may supply data voltages to data lines, driving voltages to driving voltage lines, and/or scan control signals to a scan driver. The display driver 200 may be formed, for example, of an integrated circuit (IC) bonded to the substrate SUB of the display panel 100 by a predetermined method. Examples of ICs and associated bonding methods include, but are not limited to, chip on glass (COG), chip on plastic (COP), chip on film (COF), or tape automated bonding (TAB). In one embodiment, the bonding method may include using an anisotropic conductive film (ACF) or ultrasonic bonding.

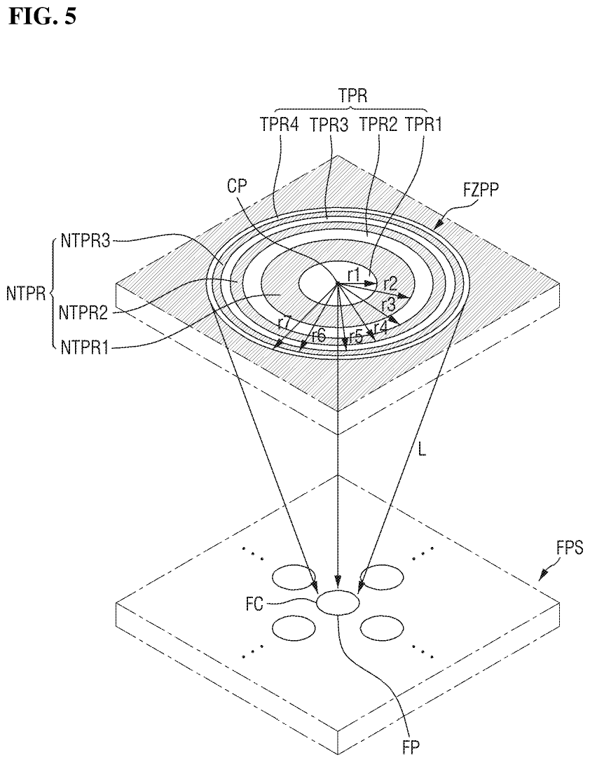

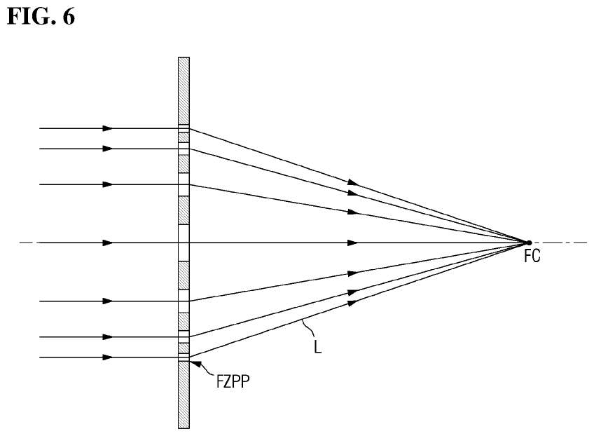

FIG. 4 is a diagram illustrating sub-pixels of a display panel and sensor pixels of a fingerprint recognition sensor according to an embodiment. FIGS. 5 and 6 are perspective views schematically showing examples of light collection through a Fresnel pattern.

Referring to FIGS. 4 to 6, the fingerprint recognition sensor FPS may include a sensor pixel FP overlapping the display layer DISL. In one embodiment, the fingerprint recognition sensor FPS may include a plurality of sensor pixels FP overlapping the display layer DISL to may detect light incident through the display layer DISL. Each sensor pixel FP may include a photoelectric conversion portion PETL. The photoelectric conversion portion PETL may be, for example, a phototransistor, a photodiode, or another type of photoelectric converter.

The display layer DISL may include a thin film transistor layer TFTL, a light emitting element layer EML on the thin film transistor layer TFTL, and an encapsulation layer TFEL on the light emitting element layer EML. Examples of the thin film transistor layer TFTL, the light emitting element layer EML, and the encapsulation layer TFEL will be described later. An example of detecting light incident through the display layer DISL by the sensor pixel FP will now be described.

When a fingerprint F is adjacent to (e.g., proximate to or in contact with) the cover window CW, light L1 output from the light emitting element layer EML may be reflected from a ridge FR or a valley FV of the fingerprint F. Light L2 reflected from the ridge FR or valley FV may reach the sensor pixel FP of the fingerprint recognition sensor FPS after having passed through the display layer DISL. The reflected light L2 may enter the photoelectric conversion portion PETL of the sensor pixel FP. Because the amount of the light L2 reflected from the ridge FR of the fingerprint F is greater than the amount of the light L2 reflected from the valley FV of the fingerprint F, the fingerprint recognition sensor FPS may recognize the fingerprint based on differences in light collection amounts.

By recognizing a fingerprint using light emitted from the light emitting element layer EML, a fingerprint recognition function may be implemented without a separate external light source. However, the present disclosure is not limited thereto. In one embodiment, the fingerprint recognition function may be implemented using a separate light source, which, for example, may correspond to a laser module or another type of light source.

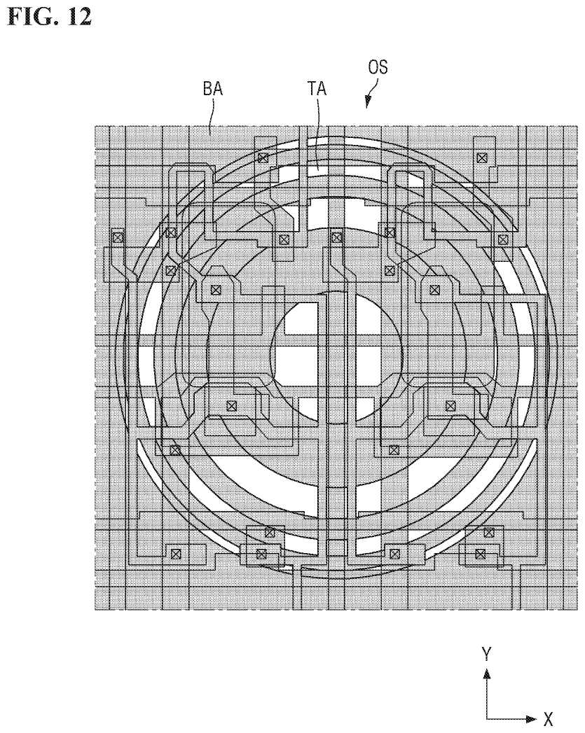

According to an embodiment, the display device 10 may include an optical system (e.g., ‘OS’ in FIG. 12) which may have a shape similar to a Fresnel pattern FZPP to collect light on the fingerprint recognition sensor FPS. The optical system may be formed through one or more wirings in the display layer DISL, examples of which will be described later.

Referring to FIG. 4, the Fresnel pattern FZPP may include a plurality of transparent regions TPR and a plurality of opaque region NTPR disposed in a predetermined (e.g., alternating) pattern. In one embodiment, each of the transparent regions TPR and opaque region NTPR may include regions disposed in a predetermined (e.g., annular) shape. In one embodiment, one region of the transparent region TPR may be located at an innermost area of the Fresnel pattern FZPP may have a different (e.g., circular) shape from other regions of the transparent region TPR. In another embodiment, one region of the opaque region NTPR may be at an innermost area of the Fresnel pattern FZPP may have a different (e.g., circular) shape from other regions of the opaque region NTPR.

In one embodiment, edges of respective portions of the transparent region TPR and/or edges of respective portions of the respective opaque region NTPR may be disposed on concentric circles having substantially the same Fresnel center point CP. In one embodiment, various regions of the transparent region TPR and/or various regions of the opaque region NTPR may have a circular or annular shape, with an nth radius (n=1, 2, 3, 4, . . . ) from the Fresnel center point CP. Here, the nth radius may be based on the product of \sqrt{n} and a first radius r1, which, for example, may be the radius of a circular transparent region TPR or a circular opaque region NTPR, whichever region is at the innermost area of the Fresnel pattern FZPP. A second radius r2 may be equal to the product of \sqrt{2} and the first radius r1. Accordingly, the area of the transparent region TPR may be substantially the same as the area of the opaque region NTPR, but these areas may be different in another embodiment.

Light passing through the transparent region TPR of the Fresnel pattern FZPP may be diffracted toward the opaque region NTPR. The diffracted light may be constructively interfered with and focused at a predetermined focal point FC. The distance to the focal point FC may be changed, for example, by adjusting the widths of the transparent region TPR and the opaque region NTPR.

FIG. 5 illustrates an example of a Fresnel pattern FZPP including four regions of the transparent region TPR and three regions of the opaque region NTPR, but the numbers of regions included in the transparent region TPR and/or the opaque region NTPR may be different in another embodiment. Also, in this example one region of the transparent region TPR is at the innermost area of the Fresnel pattern FZPP. However, one region of the opaque region NTPR may be at the innermost area of the Fresnel pattern FZPP in another embodiment.

Referring to the example of FIG. 5, the Fresnel pattern FZPP may include, from the center point CP thereof, a first transparent region TPR1 having a first radius r1 and a circular shape in plan view, a first opaque region NTPR1 outside the first transparent region TPR1 and having an annular shape whose inner radius is the first radius r1 and outer radius is a second radius r2, a second transparent region TPR2 outside the first opaque region NTPR1 and having an annular shape whose inner radius is the second radius r2 and outer radius is a third radius r3, a second opaque region NTPR2 outside the second transparent region TPR2 and having an annular shape whose inner radius is the third radius r3 and outer radius is a fourth radius r4, a third transparent region TPR3 outside the second opaque region NTPR2 and having an annular shape whose inner radius is the fourth radius r4 and outer radius is a fifth radius r5, a third opaque region NTPR3 outside the third transparent region TPR3 and having an annular shape whose inner radius is the fifth radius r5 and outer radius is a sixth radius r6, and a fourth transparent region TPR4 outside the third opaque region NTPR3 and having an annular shape whose inner radius is the sixth radius r6 and outer radius is a seventh radius r7.

Referring back to FIG. 4, in the display device 10 according to an embodiment, the optical system (e.g., see ‘OS’ in FIG. 12) may have a shape similar to the Fresnel pattern FZPP described above and may be formed at least in the fingerprint recognition area FPA using one or more opaque conductive layers in the display layer DISL. Through this arrangement, incident light may be collected on the fingerprint recognition sensor FPS to increase fingerprint recognition efficiency. Some of the conductive layer patterns in the display layer DISL may have shapes that allow them to serve as wiring or electrodes. Other conductive layer patterns in the display layer DISL may at least partially form a circular pattern, so that the entire pattern of the optical system may have a shape similar to the Fresnel pattern FZPP. Hereinafter, embodiments of an optical pattern of an optical system of a display device will be described. First, a pixel circuit of a display device according to an embodiment will be described.

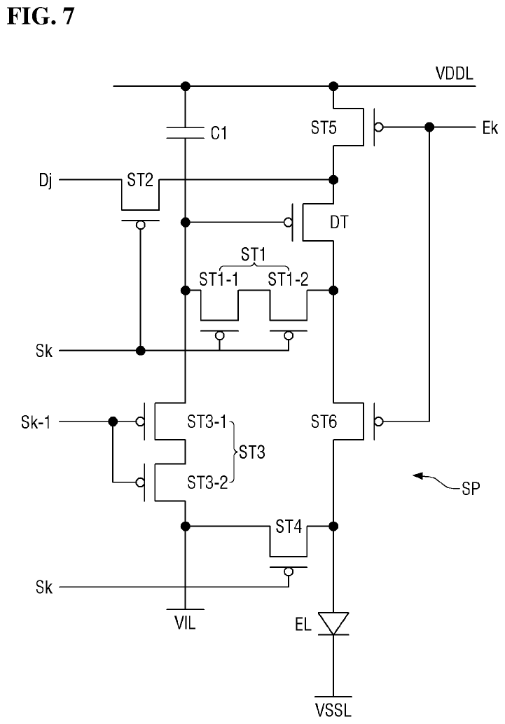

FIG. 7 is an equivalent circuit diagram of a sub-pixel SP of a display device according to an embodiment. Referring to FIG. 7, the sub-pixel SP may be connected to a (k−1)^{th} (k is a positive integer of 2 or more) scan line Sk−1, a kth scan line Sk, and a jth (j is a positive integer) data line Dj. In addition, the sub-pixel SP may be connected to a first driving voltage line VDDL to which a first driving voltage is supplied, an initialization voltage line VIL to which an initialization voltage is supplied, and a second driving voltage line VSSL to which a second driving voltage is supplied.

The sub-pixel SP may include a driving transistor DT, a light emitting element EL, switching elements, and a capacitor C1. The switching elements may include first to sixth transistors ST1, ST2, ST3, ST4, ST5 and ST6.

The driving transistor DT may include a gate electrode, a first electrode, and a second electrode and may control a drain-source current (hereinafter, referred to as “driving current”) flowing between the first electrode and the second electrode according to a data voltage applied to the gate electrode.

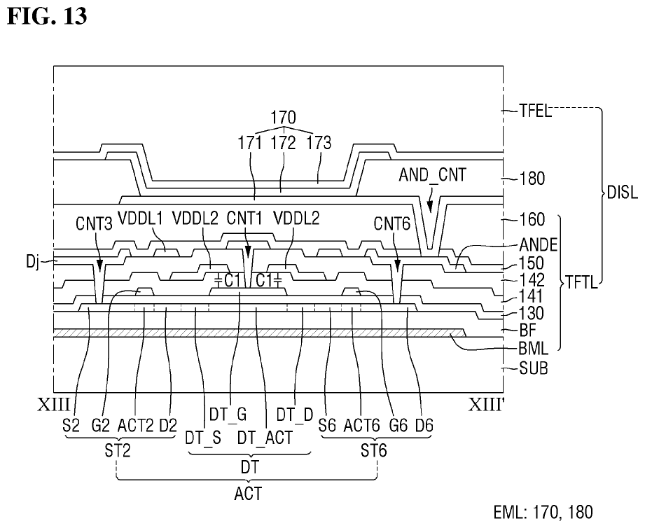

The light emitting element EL may emit light based on the driving current. The light emission amount of the light emitting element EL may be proportional to the driving current. The light emitting element EL may be, for example, an organic light emitting diode including an anode electrode (e.g., see ‘171’ in FIG. 13), a cathode electrode (e.g., see ‘173’ in FIG. 13), and an organic light emitting layer (e.g., see ‘172’ in FIG. 13) disposed between the anode electrode and the cathode electrode. The light emitting element EL may have an anode electrode connected to a first electrode of fourth transistor ST4 and a second electrode of sixth transistor ST6, and a cathode electrode connected to second driving voltage line VSSL.

The first transistor ST1 may be formed, for example, as a dual transistor including of a first-first transistor ST1-1 and a first-second transistor ST1-2. The first-first transistor ST1-1 and the first-second transistor ST1-2 may be turned on by the scan signal of the kth scan line Sk to connect the gate electrode to the second electrode of the driving transistor DT. For example, when the first-first transistor ST1-1 and the first-second transistor ST1-2 are turned on, the driving transistor DT may act as a diode because the gate electrode and the second electrode of the driving transistor DT are connected. The first-first transistor ST1-1 may have a gate electrode connected to the kth scan line Sk, a first electrode connected to the second electrode of the first-second transistor ST1-2, and a second electrode connected to the gate electrode of the driving transistor DT. The first-second transistor ST1-2 may have its gate electrode connected to the kth scan line Sk, its first electrode connected to the second electrode of the driving transistor DT, and its second electrode connected to the first electrode of the first-first transistor ST1-1.

The second transistor ST2 may be turned on by the scan signal of the kth scan line Sk to connect the first electrode of the driving transistor DT to the jth data line Dj. The second transistor ST2 may have its gate electrode connected to the kth scan line Sk, its first electrode connected to the first electrode of the driving transistor DT, and its second electrode connected to the jth data line Dj.

The third transistor ST3 may be formed, for example, as a dual transistor including a third-first transistor ST3-1 and a third-second transistor ST3-2. The third-first transistor ST3-1 and the third-second transistor ST3-2 may be turned on by the scan signal of the (k−1)th scan line Sk−1 to connect the gate electrode of the driving transistor DT to the initialization voltage line VIL. The gate electrode of the driving transistor DT may be discharged to the initialization voltage of the initialization voltage line VIL. The third-first transistor ST3-1 may have its gate electrode connected to the (k−1)th scan line Sk−1, its first electrode connected to the gate electrode of the driving transistor DT, and its second electrode connected to the first electrode of the third-second transistor ST3-2. The third-second transistor ST3-2 may have its gate electrode connected to the (k−1)th scan line Sk−1, its first electrode connected to the second electrode of the third-first transistor ST3-1, and its second electrode connected to the initialization voltage line VIL.

The fourth transistor ST4 may be turned on by the scan signal of the kth scan line Sk to connect the anode electrode of the light emitting element EL to the initialization voltage line VIL. The anode electrode of the light emitting element EL may be discharged to an initialization voltage. The fourth transistor ST4 may have its gate electrode connected to the kth scan line Sk, its first electrode connected to the anode electrode of the light emitting element EL, and its second electrode connected to the initialization voltage line VIL.

The fifth transistor ST5 may be turned on by the emission control signal of a kth light emitting line Ek to connect the first electrode of the driving transistor DT to the first driving voltage line VDDL. The fifth transistor ST5 may have its gate electrode connected to the kth light emitting line Ek, its first electrode connected to the first driving voltage line VDDL, and its second electrode connected to the first electrode of the driving transistor DT.

The sixth transistor ST6 may be connected between the second electrode of the driving transistor DT and the anode electrode of the light emitting element EL. The sixth transistor ST6 may be turned on by the emission control signal of the kth light emitting line Ek to connect the second electrode of the driving transistor DT to the anode electrode of the light emitting element EL. The sixth transistor ST6 may have its gate electrode connected to the kth light emitting line Ek, its first electrode connected to the second electrode of the driving transistor DT, and its second electrode connected to the anode electrode of the light emitting element EL. When the fifth transistor ST5 and the sixth transistor ST6 are both turned on, the driving current may be supplied to the light emitting element EL.

The capacitor C1 may be formed between the gate electrode of the driving transistor DT and the first driving voltage line VDDL. The capacitor C1 may have one electrode connected to the gate electrode of the driving transistor DT, and the other electrode connected to the first driving voltage line VDDL.

Each of the first to sixth transistors ST1, ST2, ST3, ST4, ST5, and ST6, and the driving transistor DT may be formed, for example, as a thin film transistor of the thin film transistor layer TFTL. When the first electrode of each of the driving transistor DT and the first to sixth transistors ST1 to ST6 is a source electrode, the second electrode thereof may be a drain electrode. Alternatively, when the first electrode of each of the driving transistor DT and the first to sixth transistors ST1 to ST6 is a drain electrode, the second electrode thereof may be a source electrode.

An active layer of each of the driving transistor DT and the first to sixth transistors ST1 to ST6 may include one of polysilicon, amorphous silicon, or an oxide semiconductor. When the active layer of each of the driving transistor DT and the first to sixth transistors ST1 to ST6 includes polysilicon, the active layer may be formed, for example, by a low temperature polysilicon (LTPS) process. The driving transistor DT and the first to sixth transistors ST1 to ST6 have been described as p-type metal oxide semiconductor field effect transistors (MOSFETs). In another embodiment, all or a portion of these transistors may be n-type MOSFETs.

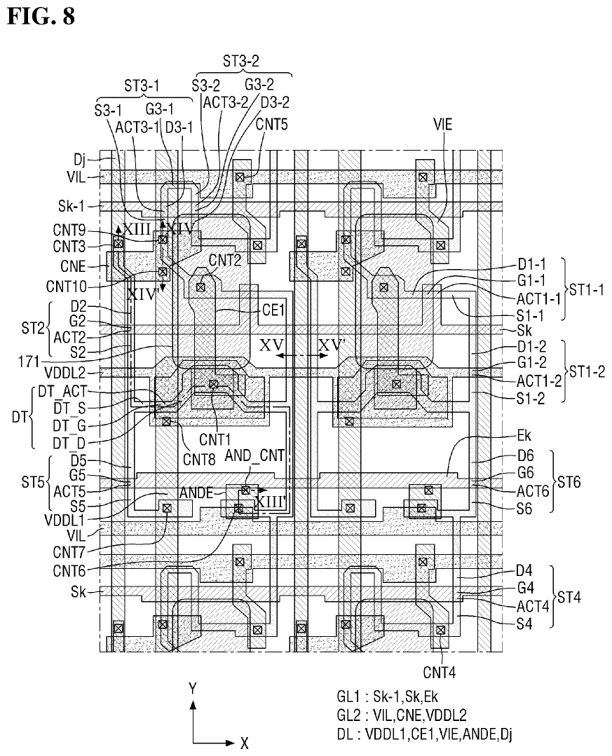

FIG. 8 is a layout diagram of sub-pixels in a fingerprint recognition area of a display device according to an embodiment. In FIG. 8, a lower metal layer BML is omitted for simplicity of description.

Referring to FIG. 8, the thin film transistor layer TFTL of the sub-pixel SP may include the driving transistor DT, the first to sixth transistors ST1 to ST6, the capacitor C1, a first connection electrode CE1, a second connection electrode VIE, a third connection electrode CNE, and an anode connection electrode ANDE.

The sub-pixel SP may overlap the (k−1)th scan line Sk−1, the kth scan line Sk, the kth light emitting line Ek, the jth data line Dj, the first driving voltage line VDDL, and the initialization voltage line VIL in the third direction Z. The sub-pixel SP may be connected to the (k−1)th scan line Sk−1, the kth scan line Sk, the jth data line Dj, and the first driving voltage line VDDL through first to sixth transistors ST1 to ST6. The (k−1)th scan line Sk−1, the kth scan line Sk, the kth light emitting line Ek, and the initialization voltage line VIL may extend in the first direction X. The jth data line Dj may extend in the second direction Y.

The first driving voltage line VDDL may include a first sub-driving voltage line VDDL1 and a second sub-driving voltage line VDDL2. The first sub-driving voltage line VDDL1 may extend in the second direction Y, and the second sub-driving voltage line VDDL2 may extend in the first direction X. The first sub-driving voltage line VDDL1 may be disposed between the jth data line Dj and the first connection electrode CE1 in the first direction X. The second sub-driving voltage line VDDL2 may be disposed between the kth scan line Sk and the kth light emitting line Ek in the second direction Y. The first sub-driving voltage line VDDL1 may be connected to the second sub-driving voltage line VDDL2 through an eighth contact hole CNT8.

The driving transistor DT may include a driving active layer DT_ACT, a driving gate electrode DT_G, a first electrode DT_S, and a second electrode DT_D. The driving active layer DT_ACT of the driving transistor DT may overlap the driving gate electrode DT_G of the driving transistor DT in the third direction Z. The driving gate electrode DT_G may be disposed on the driving active layer DT_ACT of the driving transistor DT.

The driving gate electrode DT_G may be connected to the first connection electrode CE1 through a first contact hole CNT1. The first connection electrode CE1 may be connected to the second electrode D1-1 of the first-first transistor ST1-1 through a second contact hole CNT2. Since the first connection electrode CE1 extends in the second direction Y, it may cross the kth scan line Sk.

The first electrode DT_S of the driving transistor DT may be connected to a first electrode S2 of the second transistor ST2. The second electrode DT_D of the driving transistor DT may be connected to a first electrode S1-2 of the first-second transistor ST1-2 and a first electrode S6 of the sixth transistor ST6.

As described above, in accordance with one embodiment, the first transistor ST1 may be formed of a dual transistor and may include the first-first transistor ST1-1 and the first-second transistor ST1-2.

The first-first transistor ST1-1 may include a first-first active layer ACT1-1, a first-first gate electrode G1-1, a first electrode S1-1, and the second electrode D1-1. The first-first gate electrode G1-1 of the first-first transistor ST1-1 may be a part of the kth scan line Sk and may be a region where the first-first active layer ACT1-1 of the first-first transistor ST1-1 overlaps the kth scan line Sk in the third direction Z. The first electrode S1-1 of the first-first transistor ST1-1 may be connected to a second electrode D1-2 of the first-second transistor ST1-2. The second electrode D1-1 of the first-first transistor ST1-1 may be connected to the first connection electrode CE1 through the second contact hole CNT2.

The first-second transistor ST1-2 may include a first-second active layer ACT1-2, a first-second gate electrode G1-2, the first electrode S1-2, and the second electrode D1-2. The first-second gate electrode G1-2 of the first-second transistor ST1-2 may be a part of the kth scan line Sk and may be a region where the first-second active layer ACT1-2 of the first-second transistor ST1-2 overlaps the kth scan line Sk in the third direction Z. The first electrode S1-2 of the first-second transistor ST1-2 may be connected to the second electrode DT_D of the driving transistor DT. The second electrode D1-2 of the first-second transistor ST1-2 may be connected to the first electrode S1-1 of the first-first transistor ST1-1.

The second transistor ST2 may include a second active layer ACT2, a second gate electrode G2, the first electrode S2, and a second electrode D2. The second gate electrode G2 of the second transistor ST2 may be a part of the k^{th} scan line Sk and may be a region in which the second active layer ACT2 of the second transistor ST2 overlaps the k^{th} scan line Sk in the third direction Z. The first electrode S2 of the second transistor ST2 may be connected to the first electrode DT_S of the driving transistor DT. The second electrode D2 of the second transistor ST2 may be connected to the jth data line Dj through a third contact hole CNT3.

As described above, in one embodiment, the third transistor ST3 may be formed of a dual transistor and may include the third-first transistor ST3-1 and the third-second transistor ST3-2.

The third-first transistor ST3-1 may include a third-first active layer ACT3-1, a third-first gate electrode G3-1, a first electrode S3-1, and a second electrode D3-1. The third-first gate electrode G3-1 of the third-first transistor ST3-1 may be a part of the (k−1)th scan line Sk−1 and may be a region where the third-first active layer ACT3-1 of the third-first transistor ST3-1 overlaps the (k−1)th scan line Sk−1 in the third direction Z. The first electrode S3-1 of the third-first transistor ST3-1 may be connected to the first connection electrode CE1 of the driving transistor DT through the second contact hole CNT2. The second electrode D3-1 of the third-first transistor ST3-1 may be connected to a first electrode S3-2 of the third-second transistor ST3-2.

The third-second transistor ST3-2 may include a third-second active layer ACT3-2, a third-second gate electrode G3-2, the first electrode S3-2, and a second electrode D3-2. The third-second gate electrode G3-2 of the third-second transistor ST3-2 may be a part of the (k−1)th scan line Sk−1, and may be a region where the third-second active layer ACT3-2 of the third-second transistor ST3-2 overlaps the (k−1)th scan line Sk−1 in the third direction Z. The first electrode S3-2 of the third-second transistor ST3-2 may be connected to the second electrode D3-1 of the third-first transistor ST3-1. The second electrode D3-2 of the third-second transistor ST3-2 may be connected to the second connection electrode VIE through a fourth contact hole CNT4.

The fourth transistor ST4 may include a fourth active layer ACT4, a fourth gate electrode G4, a first electrode S4, and a second electrode D4. The fourth gate electrode G4 of the fourth transistor ST4 may be a part of the kth scan line Sk, and may be a region where the fourth active layer ACT4 of the fourth transistor ST4 overlaps the kth scan line Sk in the third direction Z. The first electrode S4 of the fourth transistor ST4 may be connected to an anode connection electrode ANDE through a sixth contact hole CNT6. The anode connection electrode ANDE may be connected to the anode electrode through an anode contact hole AND_CNT. The second electrode D4 of the fourth transistor ST4 may be connected to the second connection electrode VIE through the fourth contact hole CNT4. The initialization voltage line VIL may be connected to the second connection electrode VIE through a fifth contact hole CNT5, and the second connection electrode VIE may be connected to the second electrode D3-2 of the third-second transistor ST3-2 and the second electrode D4 of the fourth transistor ST4 through the fourth contact hole CNT4. The second connection electrode VIE extends in the second direction Y and may be disposed to cross the (k−1)th scan line Sk−1.

The fifth transistor ST5 may include a fifth active layer ACT5, a fifth gate electrode G5, a first electrode S5, and a second electrode D5. The fifth gate electrode G5 of the fifth transistor ST5 may be a part of the k^{th} light emitting line Ek and may be a region where the fifth active layer ACT5 of the fifth transistor ST5 overlaps the k^{th} light emitting line Ek in the third direction Z. The first electrode S5 of the fifth transistor ST5 may be connected to the first sub-driving voltage line VDDL1 through a seventh contact hole CNT7. The second electrode D5 of the fifth transistor ST5 may be connected to the first electrode DT_S of the driving transistor DT.

The sixth transistor ST6 may include a sixth active layer ACT6, a sixth gate electrode G6, a first electrode S6, and a second electrode D6. The sixth gate electrode G6 of the sixth transistor ST6 may be a part of the k^{th} light emitting line Ek and may be a region where the sixth active layer ACT6 of the sixth transistor ST6 overlaps the k^{th} light emitting line Ek in the third direction Z. The first electrode S6 of the sixth transistor ST6 may be connected to the second electrode DT_D of the driving transistor DT. The second electrode D6 of the sixth transistor ST6 may be connected to an anode electrode 171 of the light emitting element through the sixth contact hole CNT6.

Referring to FIG. 8, a pattern (hereinafter, referred to as “upper conductive layer stacking pattern”) may be formed by projection of a first gate wiring layer GL1, a second gate wiring layer GL2, a data wiring layer DL, and the anode electrode (e.g., see ‘171’ in FIG. 13) corresponding to the opaque layers of the display layer, and may include the opaque region. However, the planar shape of the opaque region may include only the upper conductive layer stacking patterns is independent of the Fresnel pattern FZPP described above. That is, the opaque region may include only the upper conductive layer stacking patterns may not form the circular pattern of the Fresnel pattern FZPP.

To form the planar shape of the entire opaque region of the display layer in the shape similar to the Fresnel pattern FZPP, the lower metal layer BML (e.g., which is another opaque layer) may be is used. The lower metal layer BML may at least partially be formed in a portion that does not overlap the upper conductive layer stacking pattern to complement the shape of the entire optical pattern. Since the lower metal layer BML has a partial shape of the circular pattern, it may contribute to allowing the entire optical pattern to have a part of the circular pattern of the Fresnel pattern FZPP.

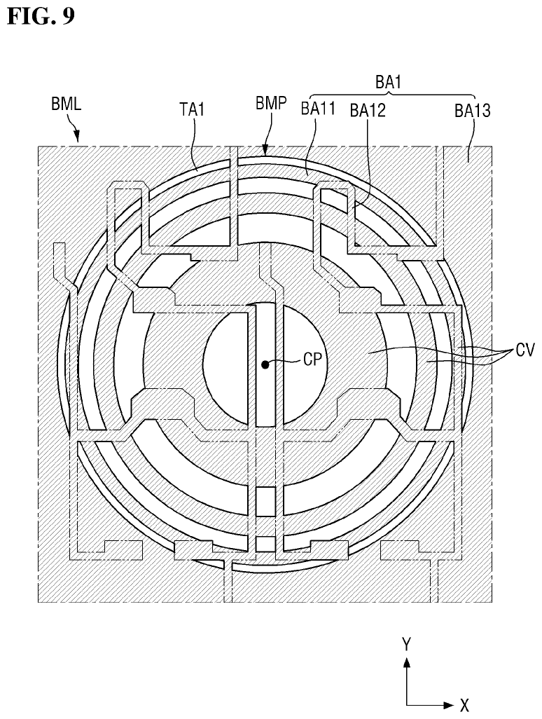

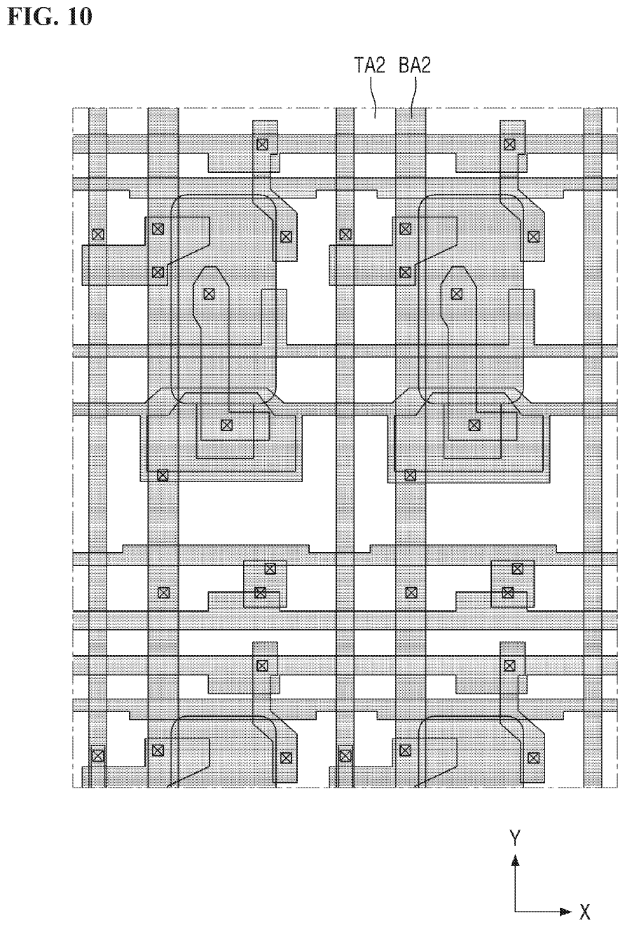

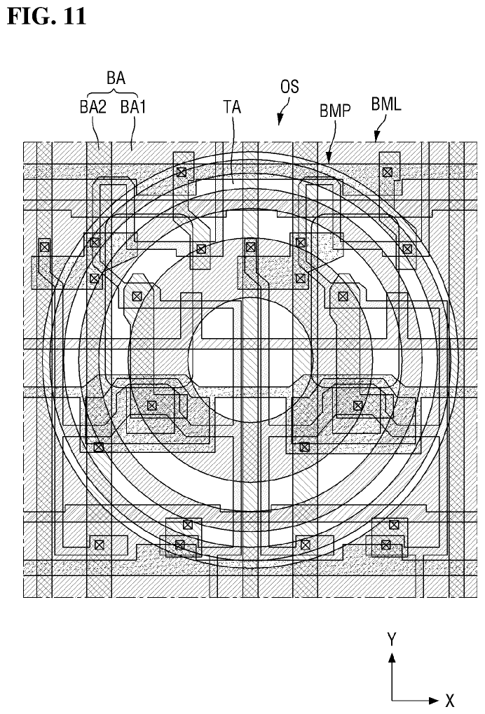

FIG. 9 is a layout diagram of a lower metal layer according to an embodiment. FIG. 10 is a plan view obtained by projecting an upper conductive layer stacking pattern according to an embodiment. FIG. 11 is a layout diagram showing both the layout of FIG. 8 and the lower metal layer layout of FIG. 9 according to an embodiment. FIG. 12 is a plan view of an optical system obtained by overlapping and projecting an upper conductive layer stacking pattern and the lower metal layer of FIG. 9 according to an embodiment.

Referring to FIGS. 4 and 9 to 12, the optical system OS may have a shape similar to the Fresnel pattern FZPP and may collect light L2 reflected from a fingerprint F. In the layout diagram of the sub-pixel SP, optical system OS having a pattern similar to the Fresnel pattern FZPP (e.g., as described above) may be formed using the lower metal layer BML, and this may be accomplished without changing the design of the first gate wiring layer GL1, the second gate wiring layer GL2, the data wiring layer DL, and the light emitting element layer EML. Thus, in at least one embodiment, a light collection effect can be obtained.

As a comparative example, if the Fresnel pattern FZPP of FIG. 5 were to be superimposed on the layout of FIG. 8, a stepped portion may exist on the top surface of a semiconductor layer ACT. Accordingly, a crack may occur in the process of applying a laser beam to the semiconductor layer ACT for silicon crystallization, which crack may adversely affect the quality of the display device 10. To prevent formation of a stepped portion on the top surface of the semiconductor layer ACT (and thus to prevent or reduce the likelihood of a crack occurring), according to an embodiment the lower metal layer BML may be provided to have a shape similar to the Fresnel pattern FZPP and may be disposed under the semiconductor layer ACT in an overlapping manner Hereinafter, the shape of the lower metal layer BML according to one or more embodiments will be described.

According to an embodiment, the lower metal layer BML may include a plurality of curved portions CV. Edges of respective ones of the curved portions CV may be disposed on concentric circles having the same lower metal center point CP. The lower metal layer BML may include a plurality of lower metal patterns BMP. The lower metal patterns BMP may be arranged in a predetermined manner (e.g., regularly arranged) in the row direction and the column direction in the lower metal layer BML, or may be arranged in a different manner, e.g., randomly arranged. Each lower metal pattern BMP may include a first light blocking portion BA1 that blocks light and a first light transmitting portion TA1 that transmits light.

The first light blocking portion BA1 may include a Fresnel area BA11 having a plurality of rings, an active area BA12 overlapping the semiconductor layer ACT of the thin film transistor layer TFTL, and an outer area BA13. As illustrated in FIG. 9, it may appear that the Fresnel area BA11, the active area BA12, and the outer area BA13 are separate layers, but this illustration is for simplicity of description. In one embodiment, and the Fresnel area BA11, the active area BA12, and the outer area BA13 may be located on the same layer and, for example, may be made of substantially the same material.

In one embodiment, the Fresnel area BA11 may have substantially the same shape as the opaque region NTPR of the Fresnel pattern FZPP described above. Edges of the respective rings of the Fresnel area BA11 may be formed on the concentric circles having the same lower metal center point CP. In addition, the rings of the Fresnel area BA11 may have substantially the same area.

The active area BA12 may connect the rings of the Fresnel area BA11 and may overlap the semiconductor layer ACT. As will be described later, the line width of the active area BA12 may be different from (e.g., greater than) the line width of the semiconductor layer ACT overlapping it. In one embodiment, the line width of the active area BA12 may be substantially the same as that of the semiconductor layer ACT. For convenience of illustration, FIG. 9 illustrates that the line width of the active area BA12 is the same as the line width of the semiconductor layer ACT shown in FIG. 8, but this is not to limit the scope of the present disclosure. But, the line width of the active area BA12 may be greater than the line width of the semiconductor layer ACT overlapping it, as described above. A stepped portion may be prevented from occurring on the top surface of the semiconductor layer ACT using the active area BA12, so that the changes of a crack forming can be reduced or prevented from occurring, for example, when a laser beam is irradiated to the semiconductor layer ACT during one or more processes, e.g., silicon crystallization. In addition, active area BA12 may electrically connect the circular rings of Fresnel area BA11.

In one lower metal pattern BMP, the outer area BA13 may be disposed to surround the Fresnel area BA11. The first light transmitting portion TA1 or the active area BA12 may be disposed between the outer area BA13 and the Fresnel area BA11. Further, the outer area BA13 may be disposed between one Fresnel area BA11 and another Fresnel area BA11.

The first light transmitting portion TA1 may be a region through which light passes in the lower metal pattern BMP, because a material forming the lower metal layer BML is not disposed in the first light transmitting portion TA1. The first light transmitting portion TA1 may not overlap the semiconductor layer ACT of the thin film transistor layer TFTL.

The upper conductive layer stacking pattern may include a second light blocking portion BA2 and a second light transmitting portion TA2, and, for example, may have the shape independent of the circular pattern of the Fresnel pattern FZPP as described above. The second light blocking portion BA2 may be defined by the first gate wiring layer GL1, the second gate wiring layer GL2, the data wiring layer DL, and the anode electrode 171 disposed to overlap each other.

As illustrated in FIG. 10, when only the upper conductive layer stacking pattern is projected, a projection image similar to the circular pattern of the Fresnel pattern FZPP may not appear. Therefore, to increase light collection efficiency, the projection image may be formed similar to the circular pattern of the Fresnel pattern FZPP. Accordingly, in an embodiment, the lower metal layer BML may have a shape similar to the circular pattern of the Fresnel pattern FZPP.

An optical system OS including the lower metal layer BML according to an embodiment will be described. The optical system OS may include a light blocking portion BA and a light transmitting portion TA formed, for example, by overlapping the thin film transistor layer TFTL and the anode electrode 171.

The light blocking portion BA of the optical system OS may include the first light blocking portion BA1 of the lower metal pattern BMP in the lower metal layer BML and the second light blocking portion BA2 of the upper conductive layer stacking pattern.

The light transmitting portion TA may be a region through which light may pass (other than the light blocking portion BA in the optical system OS) and may not overlap the anode electrode 171 and wirings made of an opaque material in the thin film transistor layer TFTL. For example, the light transmitting portion TA may not overlap the first gate wiring layer GL1, the second gate wiring layer GL2, and the data wiring layer DL.

The sensor pixel FP of the fingerprint recognition sensor FPS may sense an image of the reflected light L2 which has substantially the same shape as the light transmitting portion TA of the optical system OS. For example, the reflected light L2 focused on the sensor pixel FP may have reached it after passing through the light transmitting portion TA of the optical system OS. Hereinafter, the cross-sectional structure of the above-described display device 10 will be described in accordance with one or more embodiments.

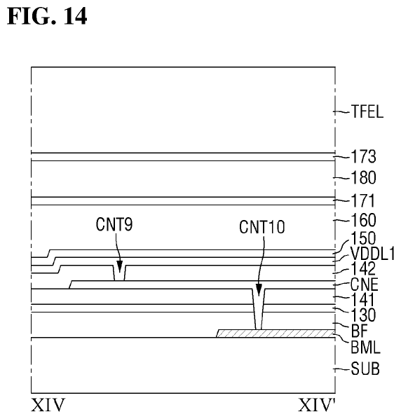

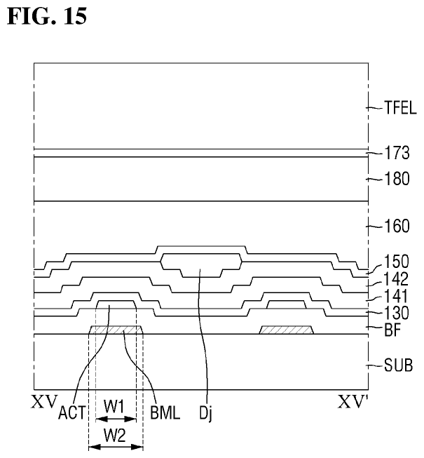

FIG. 13 is a cross-sectional view taken along line XIII-XIII′ of FIG. 8 according to one embodiment. FIG. 14 is a cross-sectional view taken along line XIV-XIV′ of FIG. 8 according to one embodiment. FIG. 15 is a cross-sectional view taken along line XV-XV′ of FIG. 8 according to one embodiment.

Referring to FIGS. 13 to 15, the thin film transistor layer TFTL, the light emitting element layer EML, and the encapsulation layer TFEL may be sequentially disposed on the substrate SUB. The thin film transistor layer TFTL may include the lower metal layer BML, the buffer layer BF, the semiconductor layer ACT, the first gate wiring layer GL1, the second gate wiring layer GL2, the data wiring layer DL, a gate insulating layer 130, a first interlayer insulating layer 141, a second interlayer insulating layer 142, a passivation layer 150, and a first organic layer 160.

The lower metal layer BML may be disposed on one surface of the substrate SUB. In one embodiment, the lower metal layer BML may entirely overlap the semiconductor layer ACT disposed thereabove. The lower metal layer BML may be formed as a single layer or multiple layers including one or more of molybdenum (Mo), aluminum (Al), chromium (Cr), gold (Au), titanium (Ti), nickel (Ni), neodymium (Nd) or copper (Cu), or an alloy thereof. In one embodiment, the lower metal layer BML may include an organic layer with pigment of a predetermined color, e.g., black.

The buffer layer BF may be disposed on the lower metal layer BML and may protect the thin film transistor layer TFTL and the light emitting element layer EML from moisture permeating through the substrate SUB susceptible to moisture permeation.

The semiconductor layer ACT may be disposed on the buffer layer BF. In one embodiment, the semiconductor layer ACT may include not only active layers DT_ACT, ACT1 to ACT6 of the driving transistor DT and the first to sixth switching transistors ST1 to ST6, but also the source electrodes DT_S, S1, S2-1, S2-2, S3-1, S3-2, S4, S5, and S6 and the drain electrodes DT_D, D1, D2-1, D2-2, D3-1, D3-2, D4, D5, and D6 of the driving transistor DT and the first to sixth switching transistors ST1 to ST6. The semiconductor layer ACT may include one or more materials. Examples include polycrystalline silicon, monocrystalline silicon, low-temperature polycrystalline silicon, amorphous silicon, or an oxide semiconductor. When the semiconductor layer ACT includes polycrystalline silicon or an oxide semiconductor, the ion-doped semiconductor layer ACT may have conductivity.

The fabricating process of the display device 10 may include an operation of applying a laser beam to a partial region of the semiconductor layer ACT for silicon crystallization. In this case, when a stepped portion exists on the top surface of the semiconductor layer ACT, a crack may occur in the area near the stepped portion, which crack may adversely affect the quality of the display device 10. Accordingly, to prevent or reduce the likelihood of a stepped portion forming on the top surface of the semiconductor layer ACT, in one embodiment the semiconductor layer ACT may be disposed to entirely overlap the lower metal layer BML. For example, the edge of the semiconductor layer ACT may be disposed above the lower metal layer BML, and the lower metal layer BML may completely cover the semiconductor layer ACT.

In one embodiment, the line width of the lower metal layer BML may be greater than the line width of the semiconductor layer ACT disposed thereabove in an overlapping manner. In one embodiment, the line width of the lower metal layer BML may be substantially the same as that of the semiconductor layer ACT. For example, when a part of the semiconductor layer ACT has a line width of a first width W1, the lower metal layer BML overlapping it may have a line width of a second width W2 greater than or equal to the first width W1. FIG. 15 illustrates an example where the second width W2 (which is the line width of the lower metal layer BML) is greater than the first width W1 which is the line width of the semiconductor layer ACT overlapping it. In another embodiment, the first width W1 may be substantially the same as the second width W2. Accordingly, the top surface of the semiconductor layer ACT may include a flat surface without a stepped portion.

The gate insulating layer 130 may be disposed on the semiconductor layer ACT and, for example, may include an inorganic layer.

The first gate wiring layer GL1 may be disposed on the gate insulating layer 130. In one embodiment, the first gate wiring layer GL1 may include not only the gate electrode of the driving transistor DT and the first to sixth gate electrodes G1 to G6 of the first to sixth switching transistors ST1 to ST6, but also the scan lines Sk−1 and Sk, and the light emitting line Ek.

The first interlayer insulating layer 141 may be disposed on the first gate wiring layer GL1 and, for example, may include an inorganic layer. In one embodiment, the first interlayer insulating layer 141 may include a plurality of inorganic layers.

The second gate wiring layer GL2 may be disposed on the first interlayer insulating layer 141 and may include the initialization voltage line VIL, the second sub-driving voltage line VDDL2, and the third connection electrode CNE. The first electrode of the capacitor C1 may be a part of the driving gate electrode DT_G of the driving transistor DT, and the second electrode of the capacitor C1 may be the second sub-driving voltage line VDDL2 overlapping the driving gate electrode DT_G of the driving transistor DT.

The second interlayer insulating layer 142 may be disposed on the second gate wiring layer GL2 and, for example, may include an inorganic layer.

The data wiring layer DL may be disposed on the second interlayer insulating layer 142. In one embodiment, the data wiring layer DL may include the first sub-driving voltage line VDDL1, the first connection electrode CE1, the second connection electrode VIE, the anode connection electrode ANDE, and the data lines Dj.

The first organic layer 160 may be disposed above the data wiring layer DL and, for example, may be a planarization layer including a flat top surface.

The passivation layer 150 may be disposed between the data wiring layer DL and the first organic layer 160 and, for example, may include an inorganic layer.

The first sub-driving voltage line VDDL1 may be electrically connected to the lower metal layer BML through a ninth contact hole CNT9 and a tenth contact hole CNT10. The voltage drop of the first driving voltage can be reduced through the electrical connection between the lower metal layer BML and the first sub-driving voltage line VDDL1. However, the present disclosure is not limited thereto, and in one embodiment the contact hole for electrically connecting the first sub-driving voltage line VDDL1 to the lower metal layer BML may be located in the non-display area NDA.

The anode contact hole AND_CNT may penetrate the passivation layer 150 and the first organic layer 160 to expose the anode connection electrode ANDE.

The light emitting element layer EML may be disposed on the thin film transistor layer TFTL and may include one or more light emitting elements 170 and a pixel defining layer 180. Each of the light emitting elements 170 may include the anode electrode 171, the organic light emitting layer 172, and the cathode electrode 173. In one embodiment, the anode electrode 171 may be disposed on the first organic layer 160 and may be connected to the anode connection electrode ANDE through the anode contact hole AND_CNT.

In a top emission structure in which light is emitted toward the cathode electrode 173 when viewed with respect to the organic light emitting layer 172, the anode electrode 171 may include a metal material having high reflectivity to have, for example, a stacked structure (Ti/Al/Ti) of aluminum and titanium, a stacked structure (ITO/Al/ITO) of aluminum and ITO, an APC alloy, and/or a stacked structure (ITO/APC/ITO) of an APC alloy and ITO. The APC alloy may correspond, for example, to an alloy of silver (Ag), palladium (Pd) and copper (Cu).

The pixel defining layer 180 includes an opening that exposes the anode electrode 171 of each sub-pixel SP and may be disposed to cover the edge of the anode electrode 171. The pixel defining layer 180 may include an organic layer including, for example, acryl resin, epoxy resin, phenolic resin, polyamide resin, polyimide resin or another material.

The organic light emitting layer 172 may be disposed on the anode electrode 171 and the pixel defining layer 180. The organic light emitting layer 172 may include an organic material to emit light in a predetermined color. In one embodiment, the organic light emitting layer 172 may include a hole transporting layer, an organic material layer, and an electron transporting layer.

The cathode electrode 173 may be disposed on the organic light emitting layer 172 and may cover the organic light emitting layer 172. The cathode electrode 173 may be, for example, a common electrode disposed in common to the sub-pixels SP. In one embodiment, the cathode electrode 173 may include a transparent conductive material (TCO) such as ITO or IZO that can transmit light or a semi-transmissive conductive material such as magnesium (Mg), silver (Ag), or an alloy of Mg and Ag.

The encapsulation layer TFEL may be disposed on the light emitting element layer EML and may include at least one inorganic layer to prevent oxygen or moisture from permeating into the light emitting element layer EML. In addition, the encapsulation layer TFEL may include at least one organic layer to protect the light emitting element layer EML from foreign substances.

According to an embodiment, the display device 10 can increase the amount of light focused on the sensor pixel FP of the fingerprint recognition sensor FPS through the lower metal layer BML including the lower metal pattern BMP. Further, since each lower metal pattern BMP includes the active area BA12 that overlaps the semiconductor layer ACT of the thin film transistor layer TFTL, the changes of a crack forming in the semiconductor layer ACT can be reduced or prevented, even when a laser beam is applied to the semiconductor layer ACT for silicon crystallization or another reason. Furthermore, the first sub-driving voltage line VDDL1 may be electrically connected to the lower metal layer BML through the third connection electrode CNE. This may reduce the voltage drop of the first driving voltage.

Another embodiment of the optical system OS will be now described. In the following description, redundant parts of the description of the optical system OS will be omitted and differences will be mainly described.

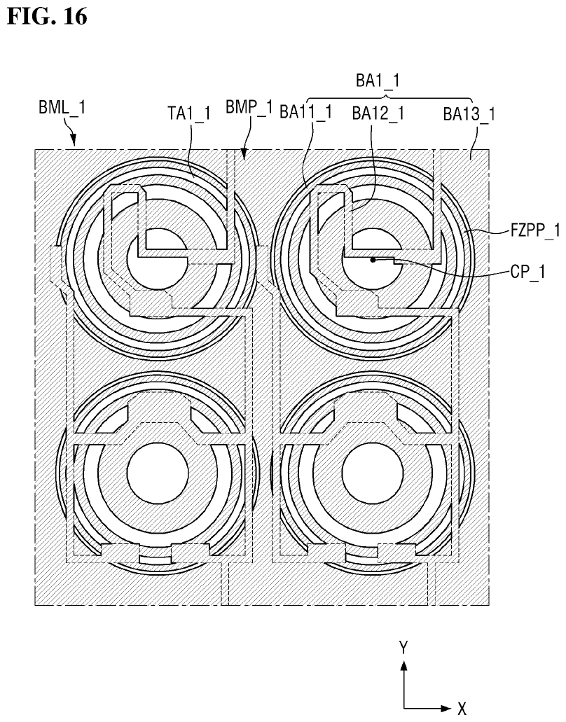

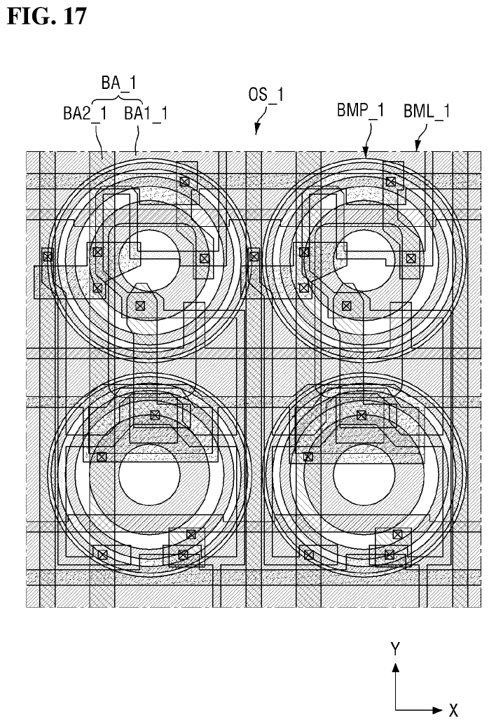

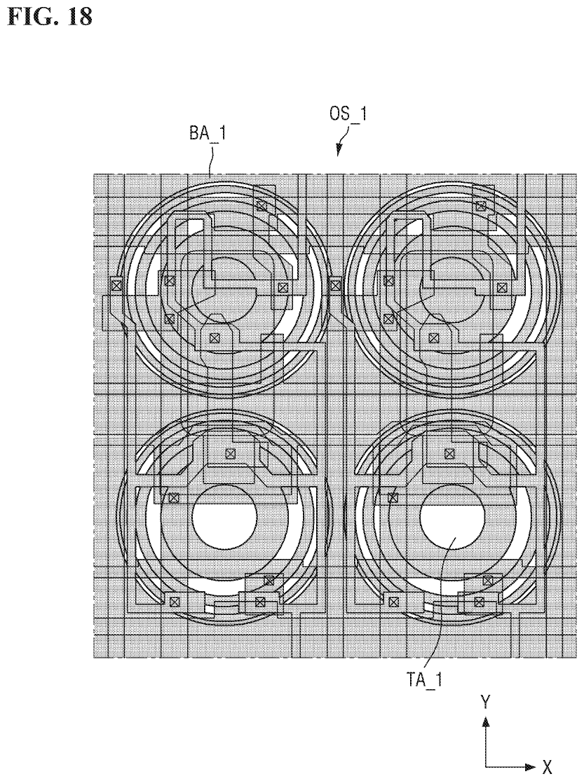

FIG. 16 is a layout diagram of a lower metal layer according to one embodiment. FIG. 17 is a layout diagram showing the layout of FIG. 8 and the layout of the lower metal layer of FIG. 16 according to an embodiment. FIG. 18 is a plan view of an optical system obtained as a result of overlapping and projecting an upper conductive layer stacking pattern and the lower metal layer of FIG. 16 according to an embodiment.

Referring to FIGS. 4 and 16 to 18, according to the present embodiment an optical system OS_1 may include a lower metal pattern BMP_1 having a shape different from one or more other embodiments of the optical system OS described herein.

FIG. 16 illustrates a layout in which a plurality of Fresnel patterns FZPP_1 are disposed for one sub-pixel SP. For example, a plan view is shown where two Fresnel patterns FZPP_1 are disposed for one sub-pixel SP in the extension direction of the jth data line Dj. If the Fresnel patterns FZPP_1 of the present comparative example were to be disposed on the layout diagram of the sub-pixel SP, a stepped portion may exist on the top surface of the semiconductor layer ACT. Accordingly, a crack may occur in the process of applying a laser beam to the semiconductor layer ACT for silicon crystallization, which crack may adversely affect the quality of the display device 10.

To prevent formation of a stepped portion on the top surface of the semiconductor layer ACT (and thus to prevent or reduce the chances of a cracking occurring), according to one embodiment shown in FIGS. 16 and 17 the lower metal layer BML_1 including the lower metal pattern BMP_1 may have a shape similar to the Fresnel pattern FZPP_1 disposed under the semiconductor layer ACT in an overlapping manner Hereinafter, the optical system OS_1 including the lower metal pattern BMP_1 according to the present embodiment will be described.

According to the present embodiment of FIGS. 16 and 17, the lower metal pattern BMP_1 in a lower metal layer BML_1 may include a first light blocking portion BA1_1 that blocks light and a first light transmitting portion TA1_1 that transmits light. The first light blocking portion BA1_1 may include a Fresnel area BA11_1, an active area BA12_1 overlapping the semiconductor layer ACT of the thin film transistor layer TFTL, and an outer area BA13_1.

The Fresnel area BA11_1 may have substantially the same shape as the opaque region NTPR of the Fresnel pattern FZPP described above. The Fresnel area BA11_1 may include a plurality of rings, and edges of the respective rings of the Fresnel area BA11_1 may be formed on concentric circles having substantially the same lower metal center point CP_1. In one embodiment, the rings of the Fresnel area BA11_1 may have substantially the same area. The active area BA12_1 may connect the rings of the Fresnel area BA11_1 and may overlap the semiconductor layer ACT.

The optical system OS_1 according to the present embodiment may include a light blocking portion BA_1 and a light transmitting portion TA_1. In the optical system OS_1 according to the present embodiment, unlike other embodiments of the optical system OS, a plurality of the lower metal patterns BMP_1 may be disposed for one sub-pixel SP. For example, two lower metal patterns BMP_1 may be disposed for one sub-pixel SP in the extending direction of the j^{th} data line Dj, but the present disclosure is not limited thereto.

The light blocking portion BA_1 of the optical system OS_1 may include the first light blocking portion BA1_1 of the lower metal pattern BMP_1 in the lower metal layer BML_1 and a second light blocking portion BA2_1 that overlaps a light blocking wiring among the wirings arranged above the lower metal layer BML_1 of the optical system OS_1. The second light blocking portion BA2_1 may be defined by the first gate wiring layer GL1, the second gate wiring layer GL2, the data wiring layer DL, and the anode electrode 171 disposed to overlap each other. The light transmitting portion TA_1 may be a region other than the light blocking portion BA_1 in the optical system OS_1, and may not overlap the anode electrode 171 and the wirings made of an opaque material in the thin film transistor layer TFTL. For example, the light transmitting portion TA_1 may not overlap the first gate wiring layer GL1, the second gate wiring layer GL2, and the data wiring layer DL.

Since the second light blocking portion BA2 in the optical system OS_1 according to the present embodiment is substantially the same as the above description with reference to FIG. 10, an additional description will be omitted.

In the above description with reference to FIG. 4, the sensor pixel FP may sense an image of the reflected light L2, which has substantially the same shape as the light transmitting portion TA_1 of the optical system OS_1. For example, the reflected light L2 focused on the sensor pixel FP may pass through the light transmitting portion TA_1 of the optical system OS_1.

According to the present embodiment, the optical system OS_1 can increase the amount of light focused on the sensor pixel FP of the fingerprint recognition sensor FPS through the lower metal layer BML_1 including the lower metal pattern BMP_1. Further, since each lower metal pattern BMP_1 includes the active area BA12_1 that overlaps the semiconductor layer ACT of the thin film transistor layer TFTL, the changes of a crack forming in the semiconductor layer ACT can be reduced or prevented even if a laser beam is applied to the semiconductor layer ACT for silicon crystallization. Furthermore, the first sub-driving voltage line VDDL1 may be electrically connected to the lower metal layer BML through the third connection electrode CNE. Accordingly, it is possible to reduce a voltage drop of the first driving voltage from occurring.

In addition, in the optical system OS_1 according to the present embodiment, the plurality of lower metal patterns BMP_1 are disposed to one sub-pixel SP, so that light collection capability can be improved, e.g., the optical system OS_1 according to the present embodiment may collect light in a more precise manner.

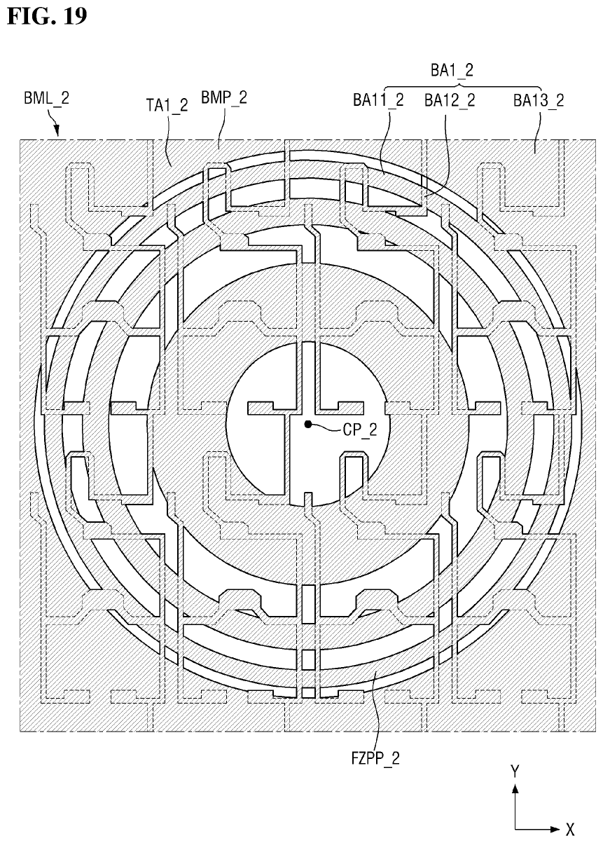

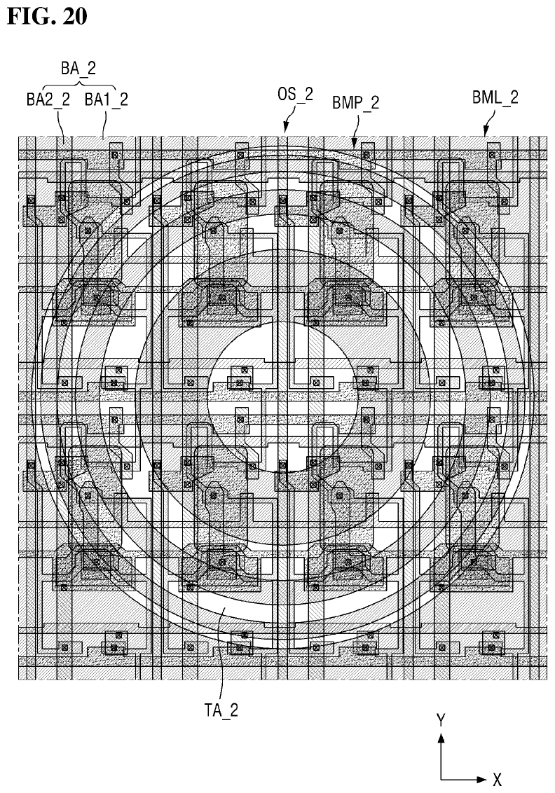

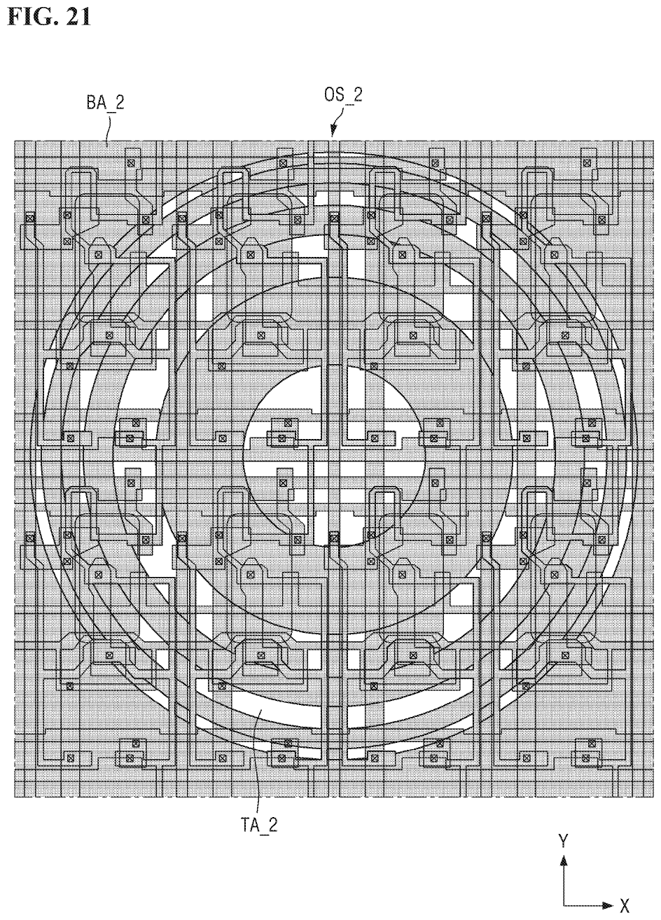

FIG. 19 is a layout diagram of a lower metal layer according to another embodiment. FIG. 20 is a layout diagram showing the layout of FIG. 8 and the layout of the lower metal layer of FIG. 19 according to an embodiment. FIG. 21 is a plan view of an optical system obtained by overlapping and projecting the upper conductive layer stacking pattern and the lower metal layer of FIG. 19 according to an embodiment.

Referring to FIGS. 4 and 19 to 21, an optical system OS_2 according to the present embodiment may include a lower metal pattern BMP_2 having a shape different from that of the optical system OS of one or more other embodiments.

As a comparative example, a plurality of sub-pixels SP may be disposed with respect to one Fresnel pattern FZPP_2. For example, one Fresnel pattern FZPP_2 may be placed for a total of eight sub-pixels SP, in which two sub-pixels SP are arranged in the extension direction of the j^{th} data line Dj and four sub-pixels SP are arranged in a direction perpendicular to the extension direction of the j^{th} data line Dj. When the Fresnel patterns FZPP_2 of the present comparative example are disposed on the layout diagram of the sub-pixel SP, a stepped portion may exist on the top surface of the semiconductor layer ACT. Accordingly, a crack may form in the process of applying a laser beam to the semiconductor layer ACT for silicon crystallization, which crack may adversely affect the quality of the display device 10. Therefore, to prevent the occurrence of a stepped portion on the top surface of the semiconductor layer ACT, according to the present embodiment the lower metal layer BML_2 including the lower metal pattern BMP_2 may have a shape similar to the Fresnel pattern FZPP_2 and may be disposed under the semiconductor layer ACT in an overlapping manner Hereinafter, the optical system OS_2 including the lower metal pattern BMP_2 according to the present embodiment will be described.

The lower metal pattern BMP_2 included in a lower metal layer BML_2 according to the present embodiment may include a first light blocking portion BA1_2 that blocks light and a first light transmitting portion TA1_2 that transmits light. The first light blocking portion BA1_2 may include a Fresnel area BA11_2, an active area BA12_2 overlapping the semiconductor layer ACT of the thin film transistor layer TFTL, and an outer area BA13_2.

In one embodiment, the Fresnel area BA11_2 may have substantially the same shape as the opaque region NTPR of the Fresnel pattern FZPP_2 described above. The Fresnel area BA11_2 may include a plurality of rings, and edges of the respective rings of the Fresnel area BA11_2 may be formed on concentric circles having substantially the same lower metal center point CP_2. Further, in one embodiment, the rings of the Fresnel area BA11_2 may have substantially the same area.

The active area BA12_2 may connect the rings of the Fresnel area BA11_2 and may overlap the semiconductor layer ACT.

The optical system OS_2 according to the present embodiment may include a light blocking portion BA_2 and a light transmitting portion TA_2. In the optical system OS_2 according to the present embodiment, unlike one or more other embodiments of the optical system OS, one lower metal pattern BMP_2 may be disposed for a total of eight sub-pixels SP, in which two sub-pixels SP are arranged in the extension direction of the j^{th} data line Dj and four sub-pixels SP are arranged in the direction perpendicular to the extension direction of the j^{th} data line Dj.

The light blocking portion BA_2 of the optical system OS_2 may include the first light blocking portion BA1_2 of the lower metal pattern BMP_2 in the lower metal layer BML_2 and a second light blocking portion BA2_2 that overlaps the light blocking wiring among wirings arranged above the lower metal layer BML_2 of the optical system OS_2. The second light blocking portion BA2_2 may be defined by the first gate wiring layer GL1, the second gate wiring layer GL2, the data wiring layer DL, and the anode electrode 171 disposed to overlap each other.

The light transmitting portion TA_2 may be a region other than the light blocking portion BA_2 in the optical system OS_2 and may not overlap the anode electrode 171 and wirings made of an opaque material in the thin film transistor layer TFTL. For example, the light transmitting portion TA_2 may not overlap the first gate wiring layer GL1, the second gate wiring layer GL2, and the data wiring layer DL.

According to the present embodiment, since the second light blocking portion BA2 in the optical system OS_2 is substantially the same as the above description with reference to FIG. 10, an additional description will be omitted.

In the above description with reference to FIG. 4, the sensor pixel FP may sense an image of reflected light L2, which has substantially the same shape as the light transmitting portion TA_2 of the optical system OS_2. For example, the reflected light L2 focused on the sensor pixel FP may pass through the light transmitting portion TA_2 of the optical system OS_2.

Also, according to the present embodiment, the optical system OS_2 can increase the amount of light focused on the sensor pixel FP of the fingerprint recognition sensor FPS through the lower metal layer BML_2 including the lower metal pattern BMP_2. Further, since each lower metal pattern BMP_2 includes the active area BA12_2 that overlaps the semiconductor layer ACT of the thin film transistor layer TFTL, the changes of a crack forming in the semiconductor layer ACT can be reduced or prevented even if a laser beam is applied to the semiconductor layer ACT for silicon crystallization. Furthermore, the first sub-driving voltage line VDDL1 may be electrically connected to the lower metal layer BML through the third connection electrode CNE. Accordingly, it is possible to reduce the voltage drop of the first driving voltage.

In addition, in the optical system OS_2 according to the present embodiment, one lower metal pattern BMP_2 is disposed to overlap the plurality of the sub-pixels SP so that the light collection amount can be further increased. Thus, the optical system OS_2 according to the present embodiment can collect a greater amount of light.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device, comprising:
a substrate;
a thin film transistor layer on the substrate; and
a light emitting electrode on the thin film transistor layer, wherein:
the thin film transistor layer includes a lower metal layer on the substrate and a semiconductor layer above and overlapping the lower metal layer, the lower metal layer including a plurality of curved portions,
edges of respective ones of the curved portions are on concentric circles having substantially a same center point, and
an edge of the semiconductor layer is on the lower metal layer.

2. The display device of claim 1, wherein the lower metal layer includes:
a first pattern region having a Fresnel zone plate shape, and
a second pattern region overlapping the semiconductor layer.

3. The display device of claim 2, wherein:
a line width of the second pattern region has a first width, and
a line width of the semiconductor layer overlapping the second pattern region has a second width which is substantially equal to or greater than the first width.

4. The display device of claim 3, wherein the semiconductor layer includes a substantially flat top surface.

5. The display device of claim 2, wherein the first pattern region includes a plurality of rings having substantially a same area.

6. The display device of claim 5, wherein the second pattern region electrically connects the rings.

7. The display device of claim 5, wherein edges of respective ones of the rings are on the concentric circles.

8. The display device of claim 1, further comprising:
a light transmitting portion and a light blocking portion overlapping the thin film transistor layer and the light emitting electrode.

9. The display device of claim 8, wherein the light transmitting portion does not overlap the thin film transistor layer and the light emitting electrode.

10. The display device of claim 8, further comprising:
a fingerprint recognition sensor under the substrate,
wherein the fingerprint recognition sensor is configured to receive light incident through the light transmitting portion.

11. The display device of claim 1, wherein the thin film transistor layer includes:
a first gate wiring layer on the semiconductor layer;
a second gate wiring layer on the first gate wiring layer; and
a data wiring layer on the second gate wiring layer and including a first driving voltage line configured to receive a first driving voltage, the second gate wiring layer including a connection electrode configured to electrically connect the first driving voltage line to the lower metal layer.

12. A display device, comprising:
a substrate;
a lower metal layer on the substrate and including a plurality of curved portions;
a semiconductor layer overlapping the lower metal layer;
a first gate wiring layer on the semiconductor layer and including a (k−1)th scan line and a k^{th} scan line disposed in parallel with each other, and a k^{th} light emitting line disposed in parallel with the (k−1)th scan line and the k^{th} scan line;
a second gate wiring layer on the first gate wiring layer and including an initialization voltage line configured to receive an initialization voltage and a connection electrode electrically connected to the lower metal layer;
a data wiring layer on the second gate wiring layer and including a j^{th} data line crossing the (k−1)th scan line and the k^{th} scan line, and a first driving voltage line configured to receive a first driving voltage and which is electrically connected to the connection electrode; and
a light emitting electrode on the data wiring layer, wherein edges of respective ones of the curved portions are on concentric circles having substantially a same center point, and wherein an edge of the semiconductor layer is on the lower metal layer.

13. The display device of claim 12, wherein the lower metal layer includes:
a first pattern region having a Fresnel zone plate shape, and
a second pattern region overlapping the semiconductor layer.

14. The display device of claim 13, wherein:
a line width of the second pattern region has a first width, and
a line width of the semiconductor layer overlapping the second pattern region has a second width substantially equal to or greater than the first width.

15. The display device of claim 14, wherein the semiconductor layer includes a substantially flat top surface.

16. The display device of claim 13, wherein the first pattern region includes a plurality of rings having substantially a same area.

17. The display device of claim 16, wherein the second pattern region electrically connects the rings.

18. The display device of claim 12, further comprising:
a light transmitting portion and a light blocking portion overlapping the semiconductor layer, the first gate wiring layer, the second gate wiring layer, the data wiring layer, and the light emitting electrode.

19. The display device of claim 18, wherein the light transmitting portion does not overlap the lower metal layer, the semiconductor layer, the first gate wiring layer, the second gate wiring layer, the data wiring layer, and the light emitting electrode.

20. The display device of claim 18, further comprising:
a fingerprint recognition sensor under the substrate and configured to receive light incident through the light transmitting portion.
